(19) United States
(12) Patent Application Publication
(10) Pub. No.: US 2024/0429633 A1
(43) Pub. Date: Dec. 26, 2024

(54) FLAT CONNECTOR

(71) Applicant: BIZLINK INTERNATIONAL CORP., New Taipei City (TW)

(72) Inventor: Chin-An HSIEH, New Taipei City (TW)

(21) Appl. No.: 18/749,629

(22) Filed: Jun. 21, 2024

(30) Foreign Application Priority Data
Jun. 21, 2023 (TW) 112123515

(51) Int. Cl. H01R 12/75; H01R 13/405

(52) U.S. Cl. CPC H01R 12/75; H01R 13/405

(57) ABSTRACT

A flat connector includes an electrical signal conductor, a substrate, and plural conductive terminals. The substrate has plural accommodating holes. Each of the conductive terminals includes a foot part, an elastic compression part, and a head part that are arranged in sequence. The foot part is attached to the substrate and is electrically connected to the electrical signal conductor. The elastic compression part is located in the accommodating hole. When the conductive terminal is not compressed, the head part penetrates out of the accommodating hole from a working surface, and the elastic compression part of the conductive terminal is suspended in the accommodating hole. When the conductive terminal is compressed, the head part of the conductive terminal moves towards the inside of the accommodating hole, and the elastic compression part is freely deformed in the accommodating hole.

### CROSS-REFERENCE TO RELATED APPLICATIONS

This application claims priority to Taiwan Application Serial Number 112123515, filed Jun. 21, 2023, which is herein incorporated by reference.

### BACKGROUND

### Field of Invention

The present disclosure relates to a flat connector structure, especially relates to a thin high-speed flat connector.

### Description of Related Art

High-speed connectors on the market for connecting servers may include types of wire-end connectors and board-end connectors based on connection methods. The terminal design of current high-speed connectors cannot balance size and signal quality under the high-density requirements of today's server contacts.

In another field of thin adapter boards, adapter boards such as PCBEAM have existed. Conductive accommodating holes (such as common PTH) in the middle of a printed circuit board are used to electrically connect the corresponding upper and lower elastic arms to form a connection matrix as a connection path for two elements, such as a design similar to the design of U.S. Pat. No. 10,135,162B1. However, the characteristic impedance of the connection positions of the upper and lower elastic arms and the conductive accommodating hole is low, which easily affects signal transmission quality, such that it is difficult to use to the field of high-speed connectors with transmission frequencies exceeding 10 Gbps.

### SUMMARY

In view of this, one purpose of the present disclosure is to provide a flat connector to solve the aforementioned problems.

In order to achieve the above purpose, according to some embodiments of the present disclosure, a flat connector includes an electrical signal conductor, a substrate, and a plurality of conductive terminals. The substrate has a plurality of accommodating holes and includes a ground conductor layer, a connection layer, and an insulating bottom plate that are stacked in sequence. Each of the conductive terminals includes a foot part, an elastic compression part, and a head part that are arranged in sequence. The foot part is attached to the substrate and is electrically connected to the electrical signal conductor, and the elastic compression part is located in one of the accommodating holes. When one of the conductive terminals is not compressed, the head part penetrates out of one of the accommodating holes from a working surface of the substrate, and the elastic compression part of the one of the conductive terminal is suspended in the one of the accommodating holes. When one of the conductive terminals is compressed, the head part of the one of the conductive terminals moves towards an inside of one of the accommodating holes, and the elastic compression part is freely deformed in the one of the accommodating holes. The ground conductor layer and the foot parts of the conductive terminals are connected to the insulating bottom plate through a same surface of the connection layer.

In some embodiments, the head part of each of the conductive terminals is substantially perpendicular to the substrate.

In some embodiments, a thickness of the ground conductor layer is the same as a thickness of the foot part of each of the conductive terminals.

In some embodiments, the connection layer is made of thermosetting material, and a portion of the foot part of each of the conductive terminals is buried in the connection layer.

In some embodiments, a portion of the foot part is attached to the substrate, another portion of the foot part extends beyond the substrate and is in a suspended arrangement, and the electrical signal conductor is welded to the portion of the foot part in the suspended arrangement of each of the conductive terminals.

In some embodiments, the conductive terminals include at least one ground terminal, and the ground terminal and the ground conductor layer are one piece formed.

In some embodiments, the flat connector further includes an inner mold and an outer mold. The inner mold covers connection positions of a cable and the conductive terminals and exposes the working surface of the substrate. The outer mold covers the inner mold and exposes the working surface of the substrate.

In some embodiments, the electrical signal conductor is a SMT pin.

According to some embodiments of the present disclosure, a flat connector includes an electrical signal conductor, a substrate, and a plurality of conductive terminals. The substrate has at least one accommodating hole and includes a ground conductor layer, a connection layer, and an insulating bottom plate that are stacked in sequence. Each of the conductive terminals includes a foot part, an elastic compression part, and a head part that are arranged in sequence. A portion of the foot part is attached to the substrate, another portion of the foot part extends beyond the substrate and is in a suspended arrangement to serve as a pin, and the elastic compression part is suspended in the accommodating hole. When one of the conductive terminals is not compressed, the head part penetrates out of the accommodating hole from a working surface of the substrate, and the elastic compression part of the one of the conductive terminals is suspended in the accommodating hole. When one of the conductive terminals is compressed, the head part of the one of the conductive terminals moves towards an inside of the accommodating hole, and the elastic compression part is freely deformed in the accommodating hole. The ground conductor layer and the foot parts of the conductive terminals are connected to the insulating bottom plate through a same surface of the connection layer.

In some embodiments, the head part of each of the conductive terminals is substantially perpendicular to the substrate.

In some embodiments, a thickness of the ground conductor layer is the same as a thickness of the foot part of each of the conductive terminals.

In some embodiments, the connection layer is made of thermosetting material, and a portion of the foot part of each of the conductive terminals is buried in the connection layer.

In some embodiments, the electrical signal conductor is welded to the portion of the foot part in the suspended arrangement of each of the conductive terminals.

In some embodiments, the conductive terminals include at least one ground terminal, and the ground terminal and the ground conductor layer are one piece formed.

In some embodiments, the flat connector further includes an inner mold and an outer mold. The inner mold covers connection positions of a cable and the conductive terminals and exposes the working surface of the substrate. The outer mold covers the inner mold and exposes the working surface of the substrate.

In some embodiments, the electrical signal conductor is a SMT pin.

To sum up, in the aforementioned embodiments of the present disclosure, since the elastic compression part of the conductive terminal is suspended in the accommodating hole, the head part of the conductive terminal can move towards the inside of the accommodating hole when the conductive terminal is compressed, and the elastic compression part may be freely deformed in the accommodating hole. As a result, the characteristic impedance of the conductive terminal does not change with contact positions, such that controlling the impedance becomes easy. This flat connector utilizing the structural design of the accommodating hole of the substrate and the conductive terminal not only can effectively reduce the size of the connector and save costs, but also can maintain the integrity of high-frequency signals, which is beneficial to the high-density requirements of servers and high-frequency transmission exceeding 10 Gbps.

### BRIEF DESCRIPTION OF THE DRAWINGS

Aspects of the present disclosure are best understood from the following detailed description when read with the accompanying figures. It is noted that, in accordance with the standard practice in the industry, various features are drawn accurately according to the real scale. In order to simplify the disclosure, some details may not be shown. However, the proportion and relative relationship of each element should be regarded as a part of the content of the present disclosure and serve as the basis for subsequent limitations.

FIG. 1A is a perspective view of a flat connector connecting a printed circuit board according to one embodiment of the present disclosure.

FIG. 1B is a partially enlarged view of the flat connector of FIG. 1A when viewed from below.

FIG. 2 is a perspective view of the flat connector of FIG. 1A when an outer mold and an inner mold are omitted.

FIG. 3A is a partially enlarged view of a substrate and a conductive terminal of FIG. 2.

FIG. 3B is a perspective view of the substrate of FIG. 3A when viewed from below.

FIG. 3C is a perspective view of the substrate of FIG. 3B when an insulating bottom plate is omitted, in which a number of accommodating holes are shown by dotted lines.

FIG. 4 is a perspective view of the conductive terminal of FIG. 3A.

FIG. 5 is a cross-sectional view of the substrate and the conductive terminal taken along line 5-5 of FIG. 3A.

FIG. 6 is a schematic view at an intermediate stage of a manufacturing method of the conductive terminal of FIG. 4.

FIG. 7A is a perspective view of a conductive terminal according to another embodiment of the present disclosure.

FIG. 7B is a perspective view of the conductive terminal of FIG. 7A when being compressed.

FIG. 8A is a perspective view of a copper plate according to one embodiment of the present disclosure.

FIG. 8B is a perspective view of the copper plate of FIG. 8A after being disposed on the insulating bottom plate and a connection layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

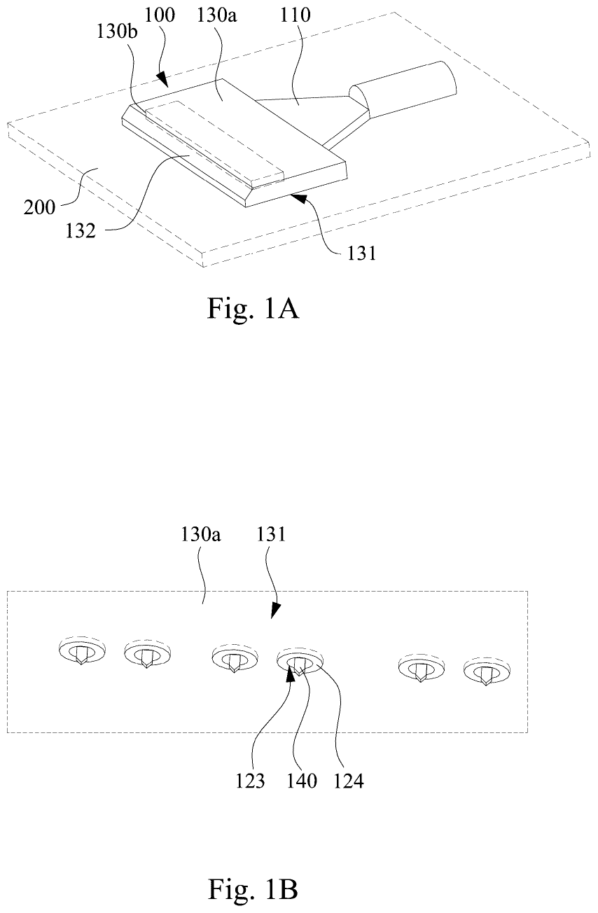

FIG. 1A is a perspective view of a flat connector 100 connecting a printed circuit board 200 according to one embodiment of the present disclosure. FIG. 1B is a partially enlarged view of the flat connector 100 of FIG. 1A when viewed from below. As shown in FIG. 1A and FIG. 1B, the flat connector 100 includes a cable 110, a substrate 120, an outer mold 130, an inner mold 130b, and conductive terminals 140. The entirety of the flat connector 100 is a flat shape, in which “flat” is referred to as 10 times the maximum thickness. The flat connector 100 may be used in a server to achieve high-speed and high-frequency connections for transmitting high-frequency signals exceeding 10 Gbps. In operation, the flat connector 100 may be compressed and fixed on the surface of the printed circuit board 200 by other components fixed on the printed circuit board 200. In addition, the flat connector 100 can further utilize conventional various spring clips/latches (not shown) and a pull strip connected to the various spring clips/latches to adjust the connection relationship between the flat connector 100 and the printed circuit board 200.

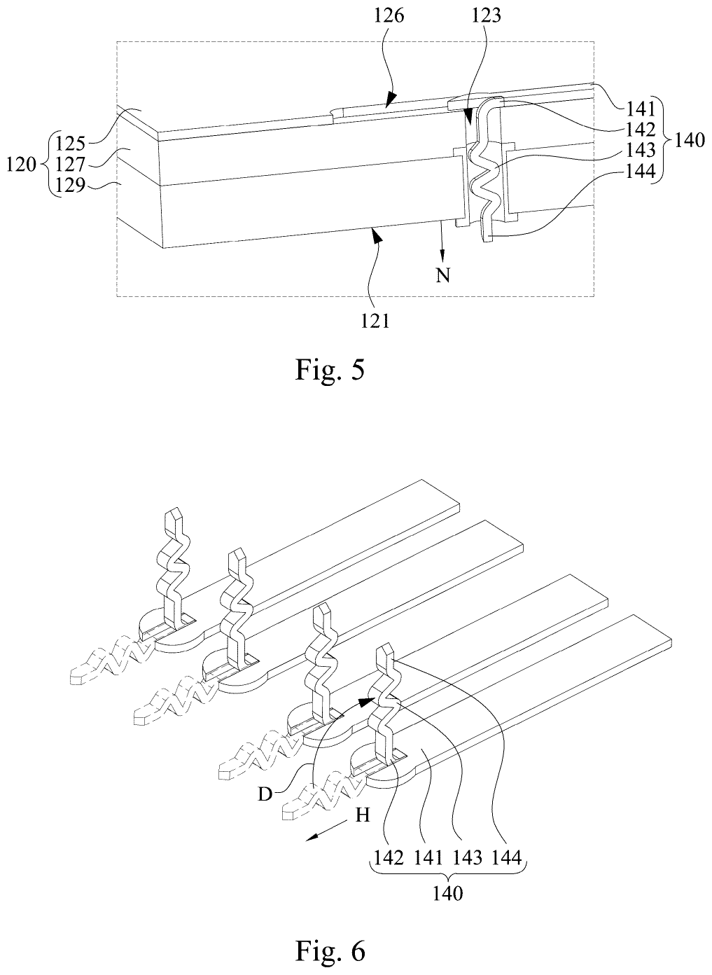

A design example of the substrate 120 in this embodiment will be described below. As shown in FIG. 5, in this embodiment, the substrate 120 is a printed circuit board (PCB) having multiple structures, and a ground conductor layer 125, a connection layer 127, and an insulating bottom plate 129 that are stacked in sequence from top to bottom.

The ground conductor layer 125 is a conductive metal, such as copper. The ground conductor layer 125 has plural non-enclosed openings extending to the sidewall of the ground conductor layer 125, thereby forming recesses 126 to allow accommodating at least one portion of the conductive terminal 140 and exposing at least one portion of the conductive terminal 140 from the top surface of the recess 126. Furthermore, an end cross-sectional surface of the conductive terminal 140 is not enclosed and covered by the ground conductor layer 125.

In this embodiment, the connection layer 127 is a prepreg. However, the connection layer 127 may be made of other insulating materials, such as other known thermosetting, thermoplastic or various adhesive materials. In this embodiment, the prepreg of the connection layer 127 can be fixed to other components connected to the prepreg after heating and curing. After the connection layer 127 is cured, the connection layer 127 includes an upper through hole structure to allow the conductive terminal 140 to pass through. The ground conductor layer 125 and the conductive terminal 140 are disposed on the same surface of the connection layer 127.

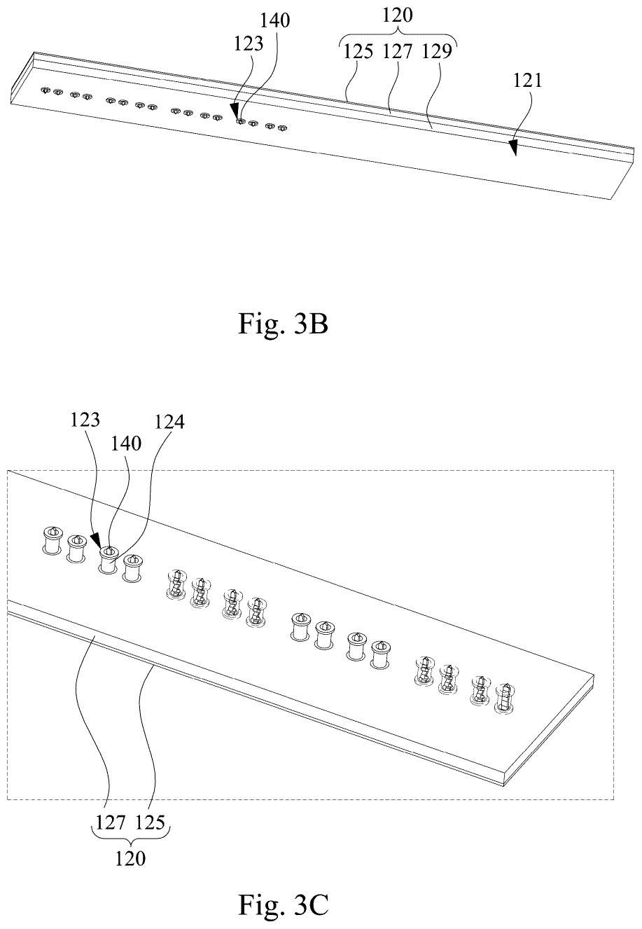

The insulating bottom plate 129 is a plate-shaped material made of polypropylene (PP). The insulating bottom plate 129 has a lower through hole structure, and the lower through hole structure is a plating through hole (PTH) having an electroplated metal layer 124. For example, the material of the electroplated metal layer 124 is copper. The electroplated metal layer 124 is located in the insulating bottom plate 129, and extends to two opposite surfaces of the insulating bottom plate 129 to form two three-dimensional ring-shaped crown portions. The upper through hole structure of the connection layer 127 and the lower through hole structure of the insulating bottom plate 129 are concentrically overlapped disposed so as form an accommodating hole 123. The accommodating hole 123 is capable of accommodating the conductive terminal 140, as shown in FIG. 5. Moreover, FIG. 3C is a perspective view of the substrate 120 of FIG. 3B when the insulating bottom plate 129 is omitted, and a number of the accommodating holes 123 are shown by dotted lines.

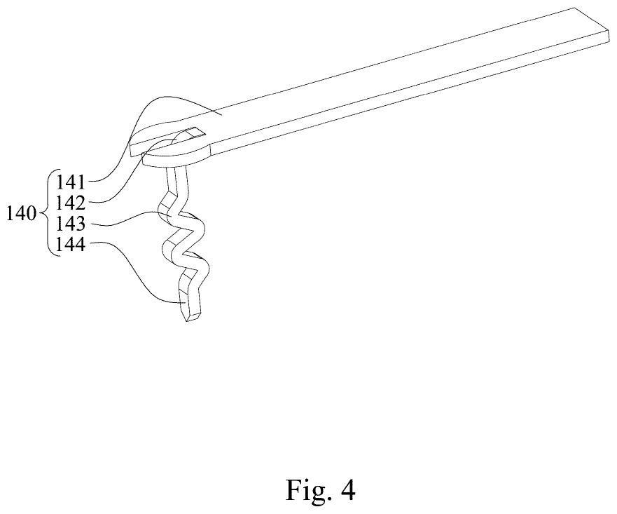

In this embodiment, the conductive terminals 140 shown in FIG. 4 are included. FIG. 4 is a perspective view of the conductive terminal 140 of FIG. 3A. FIG. 5 is a cross-sectional view of the substrate 120 and the conductive terminal 140 taken along line 5-5 of FIG. 3A. The conductive terminals 140 in this embodiment are formed by cutting or stamping from a single conductive metal plate, such as copper. As shown in FIG. 4 and FIG. 5, the conductive terminal 140 is one piece formed and sequentially has a foot part 141, a bending part 142, an elastic compression part 143, and a head part 144. In this embodiment, the length of the flat surface of the foot part 141 is greater than the thickness of the substrate 120 and the height of the elastic compression part 143. Furthermore, the entirety of the foot part 141 is substantially a flat strip metal plate, and the front end of the foot part 141 has a C-shaped structure. That is, the outer contour of the C-shaped structure is substantially circular, and the bending part 142 is formed by cutting and folding the central portion of the C-shaped structure.

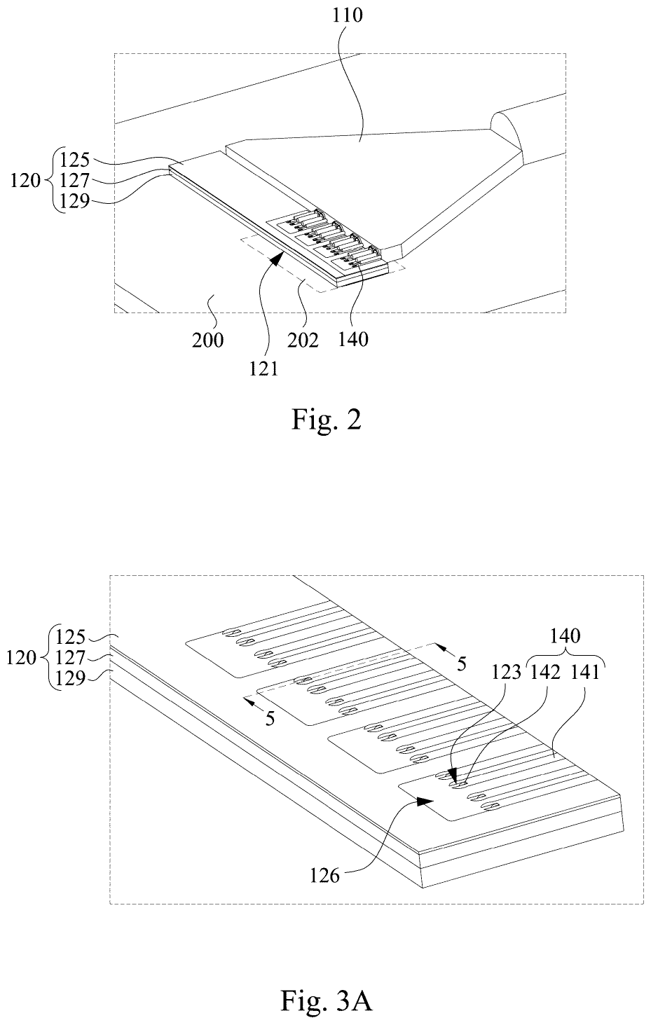

In addition, as shown in FIG. 2, the aforementioned printed circuit board 200 may be a printed circuit board in a server. The surface of the printed circuit board 200 may have plural SMT (Surface mount technology) units 202 respectively electrically connected to the conductive terminals of the flat connector 100, such as plural independent solder pads (golden finger) not electrically connected with each other or other components (e.g., solder balls).

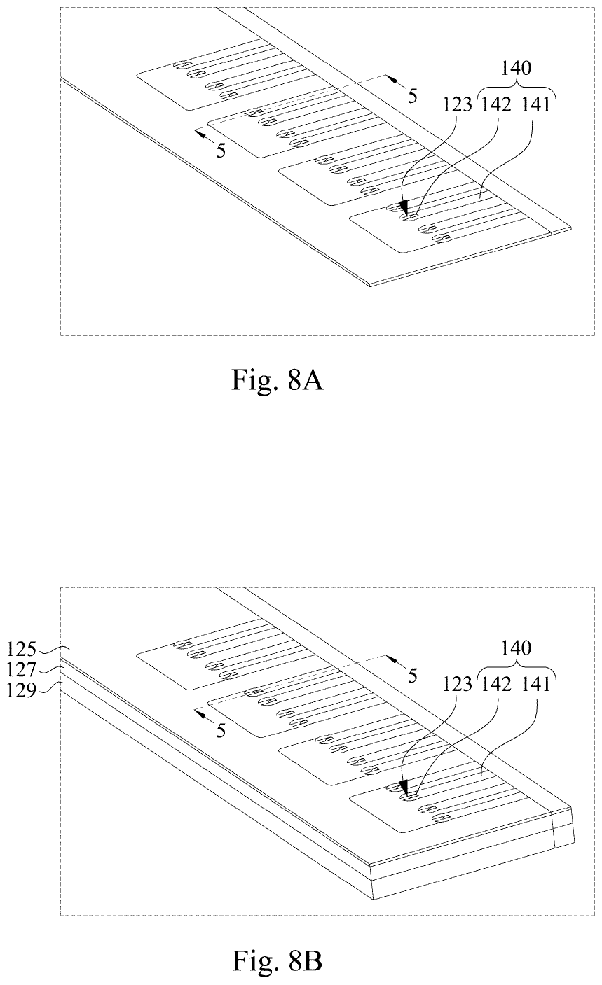

In the following description, the manufacturing process of the connector will be explained. First, a copper plate needs to be prepared. Thereafter, the copper plate is cut to form an enclosed frame structure having the conductive terminals 140. Subsequently, the front end of the conductive terminal 140 is formed into plural spring-like folding structures by pressure forming or other methods, thereby forming the elastic compression part 143 and shaping the tip of the head part 144 simultaneously. As shown in FIG. 6, at this moment, the foot part 141, the bending part 142, the elastic compression part 143, and the head part 144 are substantially located on the same flat surface, and extend in a horizontal direction H. In other words, the foot part 141, the bending part 142, the elastic compression part 143, and the head part 144 extend along the lengthwise direction of the flat surface of the foot part 141. The thickness of the ground conductor layer 125 is the same as the thickness of the foot part 141 of the conductive terminal 140. Thereafter, the bending part 142 of the conductive terminal 140 is bent along a direction D to turn the bending part 142, such that the foot part 141 is substantially perpendicular to the elastic compression part 143. At this moment, all of the conductive terminals 140 are still connected by the copper plate. The result is shown in FIG. 8A.

Thereafter, the surface of the insulating bottom plate 129 is adhered or pressed by the semi-solid connection layer 127, and plural upper through hole portions of the connection layer 127 and plural lower through hole portions or plating through hole (PTH) of the insulating bottom plate 129 are overlapped to form an matrix of the accommodating holes 123. Then, the elastic compression part 143 and the head part 144 of each of the conductive terminals 140 on the copper plate enter the plating through hole (PTH) through the upper through hole portions of the connection layer 127. At the same time, since the connection layer 127 is in a semi-cured state, the foot part 141 of each of the conductive terminals 140 and the ground conductor layer 125 are partially embedded or buried in the connection layer 127 during combination. During this period, the upper through hole portion of the connection layer 127 may be closed to merely allow the conductive terminal 140 to pass through. That is, the connection layer 127 may enclose a portion of the bending part 142. However, it is also possible that as shown in FIG. 5, a channel outside the conductive terminal 140 is retained, that is, the connection layer 127 is not completely closed. As a result, each of the conductive terminals 140 can be further fixed on the insulating bottom plate 129 so as to make it stable.

Thereafter, the connection layer 127 is heated to cure the connection layer 127. After the connection layer 127 is cured, all materials or components have been fixed. The result is shown in FIG. 8B.

Subsequently, after the assembly is cooled, a cutting tool can be used to remove portions connecting the ground conductor layer 125 and the conductive terminals 140 (i.e., the end portions at the right side of FIG. 8B) and the underlying insulating bottom plate 129, such that the conductive terminals 140 for transmitting signals and the ground conductor layer 125 are separated to form the design shown in FIG. 3A and FIG. 5. The conductive terminals 140 for grounding (ground terminals) may selectively maintain in contact with the ground conductor layer 125 or maintain one piece formed. For this reason, in this embodiment, the rear end of the foot part 141 of each of the cut signal-transmitting/ground conductive terminals 140 is aligned and coplanar with the sidewall of the substrate 120. Moreover, in another embodiment, the rear end of the foot part 141 may extend beyond the sidewall of the substrate 120 to be suspended for the use of welding the cable. If the suspended design is adopted (not shown), in the subsequent process, a resistance welding process of pressing up and down can be used to weld a cable and terminals, the cost is lower than the originally designed thermal pressing process, and the process is also relatively simple.

At this moment, the recess 126 of the ground conductor layer 125 accommodates the foot parts 141 and at least portions of the bending parts 142 of the conductive terminals 140. In this embodiment, a needle distance between the two adjacent conductive terminals 140 protruding g outward the accommodating holes 123 is less than 0.5 mm. Thereafter, for example, the cable 110 may be welded on the foot parts 141 of the terminals by hot pressing (hot bar), thereby forming the configuration shown in FIG. 2.

Thereafter, the one piece formed inner mold 130b is formed on the semi-finished product by insert molding to cover the connection positions of the cable 110 and the conductive terminals 140 and expose the working surface (e.g., a bottom surface 131) of the substrate 120. Then, the one piece formed outer mold 130a is used to further cover to provide enhanced protection, such that the outer mold 130a surrounds the inner mold 130b and exposes the working surface of the substrate 120. That is, the conductive terminals 140 are electrically connected to the cable 110. In addition, one end of the conductive terminal 140 protrudes outward from the bottom surface 131 of the outer mold 130a, and can be used to electrically connect the contacts of the printed circuit board 200. The result is shown in FIG. 1A.

Moreover, the outer mold 130a includes a front protrusion 132 with an inclined surface. When the flat connector 100 is connected to the printed circuit board 200, each surface of the front protrusion 132 of the outer mold 130a may correspondingly serve as a separation fulcrum for rotation relative to the printed circuit board 200 based on different designs. The inner mold 130b covers the connection position of the cable 110 and the printed circuit board 200. The foot part 141 of the conductive terminal 140 connects the cable 110 (see FIG. 2), and is flat.

After the production is completed, the substrate 120 of the flat connector 100 is covered by the inner mold 130b of FIG. 1A except the bottom surface 121 of the substrate 120. The conductive terminal 140 passes through the top surface of the substrate 120 and protrudes outward from the bottom surface 121 of the substrate 120, such that the tips of the conductive terminals 140 can be respectively electrically connected to the SMT units 202 that are independent and not electrically connected with each other when the flat connector 100 is attached to the printed circuit board 200 by pressing.

At this moment, the elastic compression part 143 of the conductive terminal 140 is located in the accommodating hole 123 of the substrate 120. In detail, the elastic compression part 143 of the conductive terminal 140 is surrounded by the electroplated metal layer 124. When the conductive terminal 140 is not compressed, the elastic compression part 143 of the conductive terminal 140 is suspended in the accommodating hole 123. In addition, the head part 144 of the conductive terminal 140 is pointed. The head part 144 of the conductive terminal 140 is substantially in a vertical arrangement when the head part 144 is not compressed. That is, an angle between the end of the conductive terminal 140 and the normal line N of the bottom surface 121 of the substrate 120 is in a range from 0 degree to 20 degrees. In this embodiment, the head part 144 of the conductive terminal 140 is parallel to the normal line N. In other words, the head part 144 is substantially perpendicular to the bottom surface 121 of the substrate 120.

In another aspect, since no fixing material is injected into the accommodating hole 123, the head part 144 of the conductive terminal 140 can be retracted to the accommodating hole 123 (moved to the inside of the accommodating hole 123) when the head part 144 of the conductive terminal 140 is compressed (e.g., abuts against the printed circuit board 200 of FIG. 2), and the elastic compression part 143 of the conductive terminal 140 can be freely deformed in the accommodating hole 123. The term “freely deformed” is referred to as at least some degree of deformation for the elastic compression part 143 due to the accommodating hole 123 without injected material.

Through the configuration of the conductive terminal 140 and the accommodating hole 123 of the substrate 120, the characteristic impedance of the conductive terminal 140 does not change with contact positions, such that controlling the impedance becomes easy.

This flat connector 100 (see FIG. 1A) utilizing the designs of the aforementioned conductive terminal 140 and the accommodating hole 123 of the substrate 120 not only can effectively reduce the size of the connector and save costs, but also can maintain the integrity of high-frequency signals, which is beneficial to the high-density requirements of servers and high-frequency transmission exceeding 10 Gbps.

It is to be noted that the connection relationships, the materials, and the advantages of the elements described above will not be repeated in the following description. In the following description, other types of flat connectors will be explained.

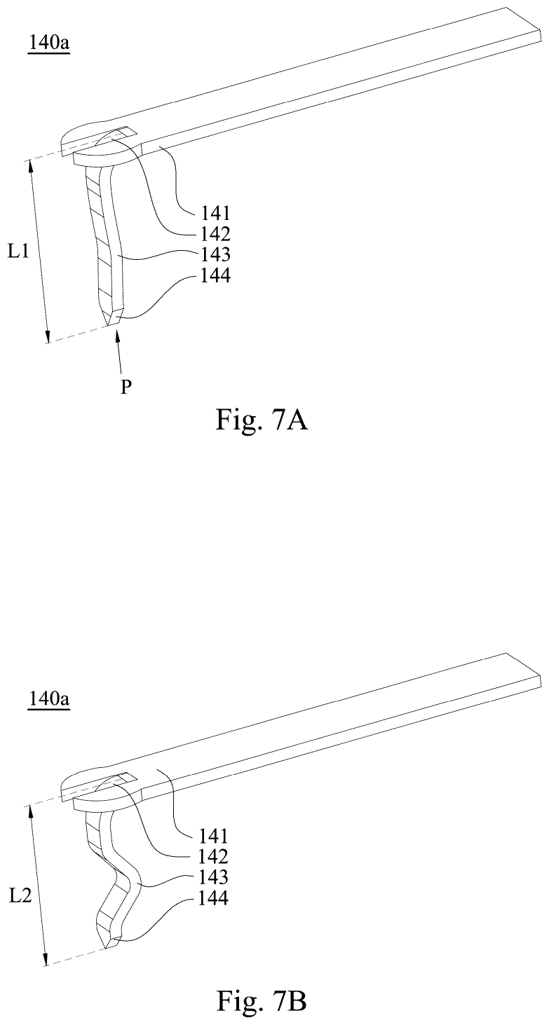

FIG. 7A is a perspective view of a conductive terminal 140a according to another embodiment of the present disclosure. FIG. 7B is a perspective view of the conductive terminal 140a of FIG. 7A when being compressed. As shown in FIG. 7A and FIG. 7B, the conductive terminal 140a includes the foot part 141, the bending part 142, the elastic compression part 143, and the head part that 144 are arranged in sequence. The difference between this embodiment and the embodiment of FIG. 4 is that the conductive terminal 140a is more flexible (e.g., changing material or thickness), such that the elastic compression part 143 of the conductive terminal 140a is straighter when the conductive terminal 140a is not compressed. However, when the conductive terminal 140a is under a pressure P, a length L1 extending from the bending part 142 to the head part that 144 can be shortened to a length L2, and an elastic compression part is formed at the elastic compression part 143 of the conductive terminal 140a. The conductive terminal 140a may be used in the aforementioned flat connector 100 of FIG. 1A, and has the same advantages as the conductive terminal 140.

Furthermore, in another embodiment, after the connection layer 127 is heated and melted, the connection layer 127 adheres a surface of the foot part 141 of the conductive terminal 140 such that a portion of the surface of the foot part 141 is buried in the connection layer 127. At this moment, the connection layer 127 covers a portion of the bending part 142, and seals the upper through hole of the connection layer 127 to be closed. As a result, each of the conductive terminals 140 can be further fixed on the insulating bottom plate 129, thereby improving reliability.

It is worth mentioning that this flat connector not only can act as a wire-end connector shown in FIG. 2, but also can be changed to act as a board-end connector (not shown) after slight adjustments. For example, the foot part 141 of the conductive terminal 140 can be extended outward and beyond the substrate so as to be suspended or connect another external pin terminal by welding, and thus the flat connector may serve as an SMT connector. Alternatively, the designed cable 110 in FIG. 1A is replaced with independent SMT pin terminals that are welded to the foot parts 141 of the conductive terminals 140, which can enable changing the connector to be a board-end connector. The conductor as the aforementioned cable or SMT pin terminal for transmitting electrical signals can be called an electrical signal conductor.

In summary, since the elastic compression part of the conductive terminal has an elastic compression part suspended in the accommodating hole, the head part of the conductive terminal can be retracted to the inside of the accommodating hole when the conductive terminal is compressed, and the elastic compression part is freely deformed in the accommodating hole. As a result, the characteristic impedance of the conductive terminal does not change with contact positions, such that controlling the impedance becomes easy. This flat connector utilizing the structural design of the accommodating hole of the substrate and the conductive terminal not only can effectively reduce the size of the connector and save costs, but also can maintain the integrity of high-frequency signals, which is beneficial to the high-density requirements of servers and high-frequency transmission exceeding 10 Gbps.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A flat connector, comprising:
an electrical signal conductor;
a substrate having a plurality of accommodating holes and comprising a ground conductor layer, a connection layer, and an insulating bottom plate that are stacked in sequence; and
a plurality of conductive terminals, wherein each of the conductive terminals comprises a foot part, an elastic compression part, and a head part that are arranged in sequence, the foot part is attached to the substrate and is electrically connected to the electrical signal conductor, and the elastic compression part is located in one of the accommodating holes, wherein
when one of the conductive terminals is not compressed, the head part penetrates out of one of the accommodating holes from a working surface of the substrate, and the elastic compression part of the one of the conductive terminal is suspended in the one of the accommodating holes;
when one of the conductive terminals is compressed, the head part of the one of the conductive terminals moves towards an inside of one of the accommodating holes, and the elastic compression part is freely deformed in the one of the accommodating holes;
the ground conductor layer and the foot parts of the conductive terminals are connected to the insulating bottom plate through a same surface of the connection layer.

2. The flat connector of claim 1, wherein the head part of each of the conductive terminals is substantially perpendicular to the substrate.

3. The flat connector of claim 1, wherein a thickness of the ground conductor layer is the same as a thickness of the foot part of each of the conductive terminals.

4. The flat connector of claim 3, wherein the connection layer is made of thermosetting material, and a portion of the foot part of each of the conductive terminals is buried in the connection layer.

5. The flat connector of claim 3, wherein a portion of the foot part is attached to the substrate, another portion of the foot part extends beyond the substrate and is in a suspended arrangement, and the electrical signal conductor is welded to the portion of the foot part in the suspended arrangement of each of the conductive terminals.

6. The flat connector of claim 1, wherein the conductive terminals comprise at least one ground terminal, and the ground terminal and the ground conductor layer are one piece formed.

7. The flat connector of claim 1, further comprising:
an inner mold covering connection positions of a cable and the conductive terminals and exposing the working surface of the substrate; and
an outer mold covering the inner mold and exposing the working surface of the substrate.

8. The flat connector of claim 1, wherein the electrical signal conductor is a SMT pin.

9. A flat connector, comprising:
an electrical signal conductor;
a substrate having at least one accommodating hole and comprising a ground conductor layer, a connection layer, and an insulating bottom plate that are stacked in sequence; and
a plurality of conductive terminals, wherein each of the conductive terminals comprises a foot part, an elastic compression part, and a head part that are arranged in sequence, a portion of the foot part is attached to the substrate, another portion of the foot part extends beyond the substrate and is in a suspended arrangement to serve as a pin, and the elastic compression part is suspended in the accommodating hole,
wherein
when one of the conductive terminals is not compressed, the head part penetrates out of the accommodating hole from a working surface of the substrate, and the elastic compression part of the one of the conductive terminals is suspended in the accommodating hole;
when one of the conductive terminals is compressed, the head part of the one of the conductive terminals moves towards an inside of the accommodating hole, and the elastic compression part is freely deformed in the accommodating hole;
the ground conductor layer and the foot parts of the conductive terminals are connected to the insulating bottom plate through a same surface of the connection layer.

10. The flat connector of claim 9, wherein the head part of each of the conductive terminals is substantially perpendicular to the substrate.

11. The flat connector of claim 9, wherein a thickness of the ground conductor layer is the same as a thickness of the foot part of each of the conductive terminals.

12. The flat connector of claim 11, wherein the connection layer is made of thermosetting material, and a portion of the foot part of each of the conductive terminals is buried in the connection layer.

13. The flat connector of claim 11, wherein the electrical signal conductor is welded to the portion of the foot part in the suspended arrangement of each of the conductive terminals.

14. The flat connector of claim 9, wherein the conductive terminals comprise at least one ground terminal, and the ground terminal and the ground conductor layer are one piece formed.

15. The flat connector of claim 9, further comprising:
an inner mold covering connection positions of a cable and the conductive terminals and exposing the working surface of the substrate; and
an outer mold covering the inner mold and exposing the working surface of the substrate.

16. The flat connector of claim 9, wherein the electrical signal conductor is a SMT pin.
